(19) United States
(12) Patent Application Publication
(10) Pub. No.: US 2013/0300266 A1
(43) Pub. Date: Nov. 14, 2013

(54) Modular Containment System

(71) Applicant: PANDUIT CORP., Tinley Park, IL (US)

(72) Inventors: Samuel C. Ramey, Naperville, IL (US); David R. Davis, New Lenox, IL (US); Samuel M. Marrs, Bradley, IL (US)

(73) Assignee: Panduit Corp., Tinley Park, IL (US)

(21) Appl. No.: 13/888,972

(22) Filed: May 7, 2013

Related U.S. Application Data
(60) Provisional application No. 61/654,137, filed on Jun. 1, 2012.
(60) Provisional application No. 61/645,725, filed on May 11, 2012.

(51) Int. Cl. H05K 5/02; A47B 87/02

(52) U.S. Cl. CPC H05K 5/0213; A47B 87/0276
USPC 312/111; 312/236

(57) ABSTRACT

The present invention is directed to a modular containment system that redirects exhaust from cabinets without altering the cabinet. The modular containment system includes a docking station having a first and second bay. The first bay has a first side frame and a second side frame. A top support joins the front of the first and second side frames and cross bars join the back of the first and second side frames. The second bay is connected to the first bay. The second bay has a third side frame. The second bay also has cross bars and a top support that join the second and third side frames. A cabinet is positioned within one of the first and second bays.

### CROSS-REFERENCE TO RELATED APPLICATIONS

This application claims priority to U.S. Provisional Application No. 61/654,137, filed Jun. 1, 2012, and U.S. Provisional Application No. 61/645,725, filed May 11, 2012, the subject matter of which is hereby incorporated by reference in its entirety.

### BACKGROUND OF THE INVENTION

The present invention relates to a modular containment system, and more particularly, to a modular containment system for network cabinets or equipment racks.

### SUMMARY

The present invention is directed to a modular containment system that redirects exhaust air from contained cabinets or racks without altering the cabinet or rack. The modular containment system includes a docking station with a plurality of bays. A first bay includes a first side frame and a second side frame with a top support and cross bars joining the first and second side frames. A second bay is connected to the first bay. The second bay including a third side frame, cross bars that join the second and third side frames and a top support that joins the second and third side frames. Each bay receives a cabinet or rack to form the containment system. The exhaust air is directed out of the containment system via a vertical exhaust duct. Alternatively, the exhaust air is cooled via a cooling unit installed in one of the bays.

### BRIEF DESCRIPTION OF THE DRAWINGS

FIG. 1 is a front perspective view of the modular docking station of the present invention with vertical exhaust ducts.

FIG. 2 is a rear perspective view of the modular docking station of the present invention with vertical exhaust ducts.

FIG. 3 is a perspective view of a docking frame of an individual bay that forms the modular docking station of FIG. 1.

FIG. 4 is a front perspective view of the bay of FIG. 3 with a vertical exhaust duct, side panel and cabinet seals.

FIG. 5 is a rear perspective view of the bay of FIG. 4 with a rear door.

FIG. 6 is a perspective view of a bay with a second bay positioned to join the first bay to form a modular docking station.

FIG. 7 is a perspective view of a docking station with a cabinet positioned to slide into a bay in the docking station.

FIG. 8 is a front perspective view of a modular docking station of the present invention with a cooling unit.

FIG. 9 is a rear perspective view of the modular docking station of FIG. 8.

FIG. 10 is a perspective view of the modular docking station of FIG. 8 with the cooling unit positioned to slide into a bay in the docking station.

FIG. 11 is a partial top view of the modular docking station of FIG. 8 with arrows illustrating the air flow out of the cooling unit, through the adjacent cabinets and through the docking station.

FIG. 12 is an exploded perspective view of an alternative modular containment system for an equipment rack.

FIG. 13 is an exploded perspective view of the equipment rack with equipment positioned to be installed in the equipment rack.

FIG. 14 is a perspective view of the modular containment system of FIG. 12 with the equipment rack of FIG. 13.

FIG. 15 is a perspective view of the modular containment system of FIG. 14 with the front door open and the equipment rack positioned to be rolled into the modular containment system.

FIG. 16 is a perspective view of the equipment rack of FIG. 15 with a bottom seal.

FIG. 17 is a top view of the modular containment system of FIG. 14 with equipment racks installed therein.

FIG. 18 is a perspective view of an alternative modular containment system with stationary equipment mounting rails installed in the system.

FIG. 19 is a perspective view of an alternative modular containment system with vertical exhaust ducts installed on the system.

FIG. 20 is a perspective view of an alternative modular containment system with an air conditioner installed on the system.

FIG. 21 is a perspective view of an alternative modular containment system containing a cold aisle.

FIG. 22 is a perspective view of an alternative modular containment system with an in-row cooler protruding from the system.

FIG. 23 is a top view of the modular containment system with the in-row cooler of FIG. 22.

FIG. 24 is a perspective view of the modular containment system of FIG. 22 with an in-row cooler completely installed in the system.

FIG. 25 is a top view of the modular containment system of FIG. 24 with an in-row cooler completely installed in the system.

### DETAILED DESCRIPTION

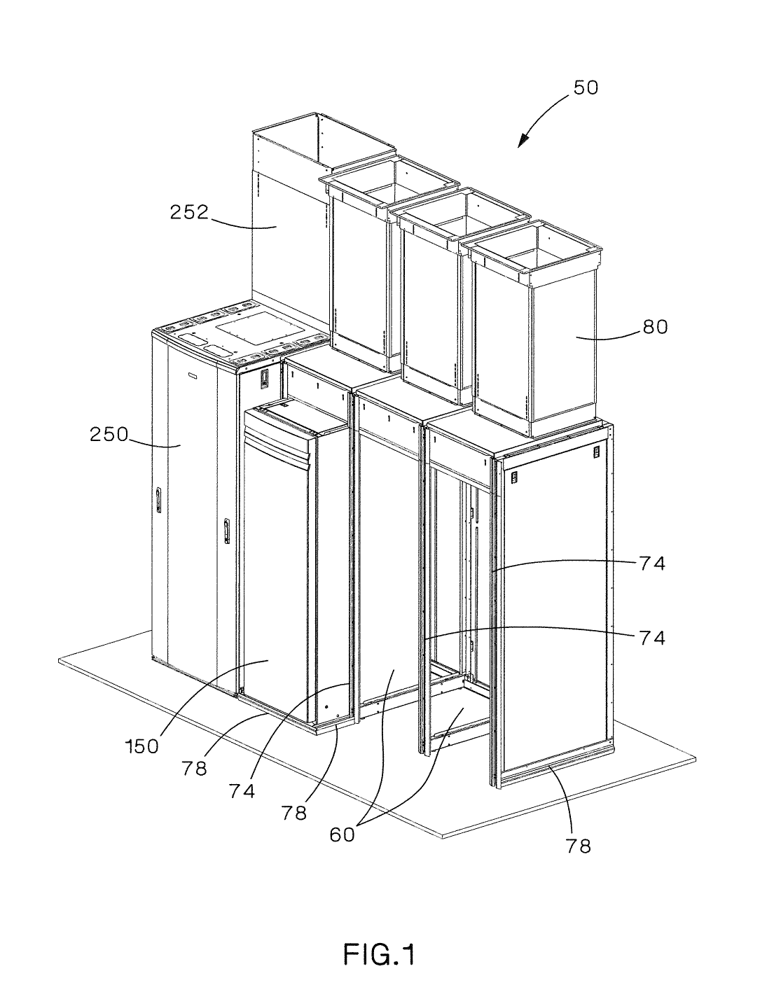

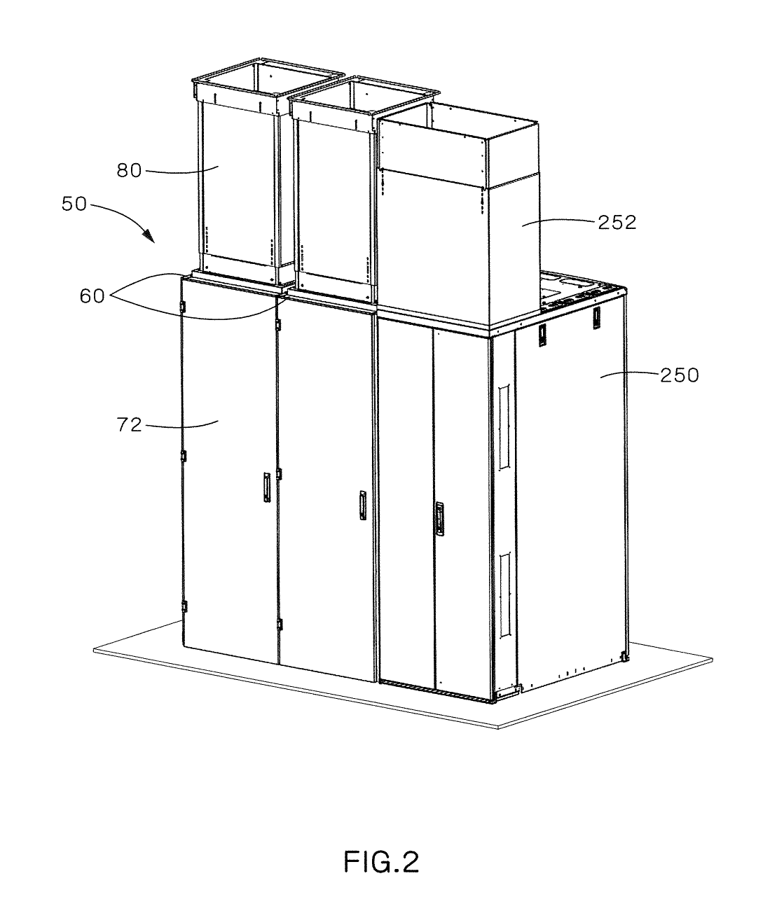

FIGS. 1 and 2 illustrate the modular docking station 50 of the present invention with vertical exhaust ducts 80. As illustrated in FIGS. 1 and 2, the docking station 50 can be positioned adjacent to a Net-Access™ cabinet 250 with a vertical exhaust duct 252. The docking station 50 provides individual bays 60 for storage of cabinets 150 that are traditionally not contained. The modular docking station 50 with the vertical exhaust ducts 80 enables cabinets 150 to be converted to a vertical exhaust duct system without altering the cabinets 150 by installing the cabinets 150 in the docking station 50.

The modular design allows for multiple bays 60 to be constructed and installed ahead of demand. The individual bays 60 of the docking station 50 may then be filled with cabinets 150 as needed.

FIG. 2 illustrates the back of the modular docking station 50. Each bay 60 includes a solid rear door 72. The rear door 72 seals and provides access to the cabling in the cabinets 150 positioned in the bays 60 of the docking station 50.

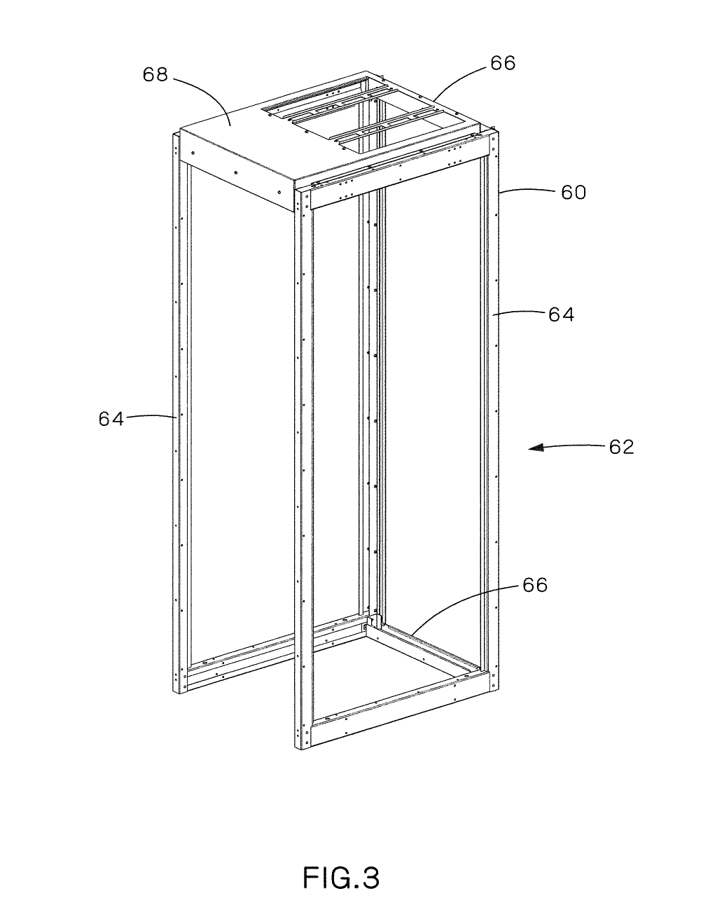

FIGS. 3-5 illustrate the structure of the individual bays 60 of the docking station 50. FIG. 3 illustrates a docking frame 62 that includes two rectangular side frames 64. The docking frame 62 also includes two cross bars 66 that connect the side frames 64 at the back of the docking frame 62. A top support 68 extends between the side frames 64 at the front of the docking frame 62.

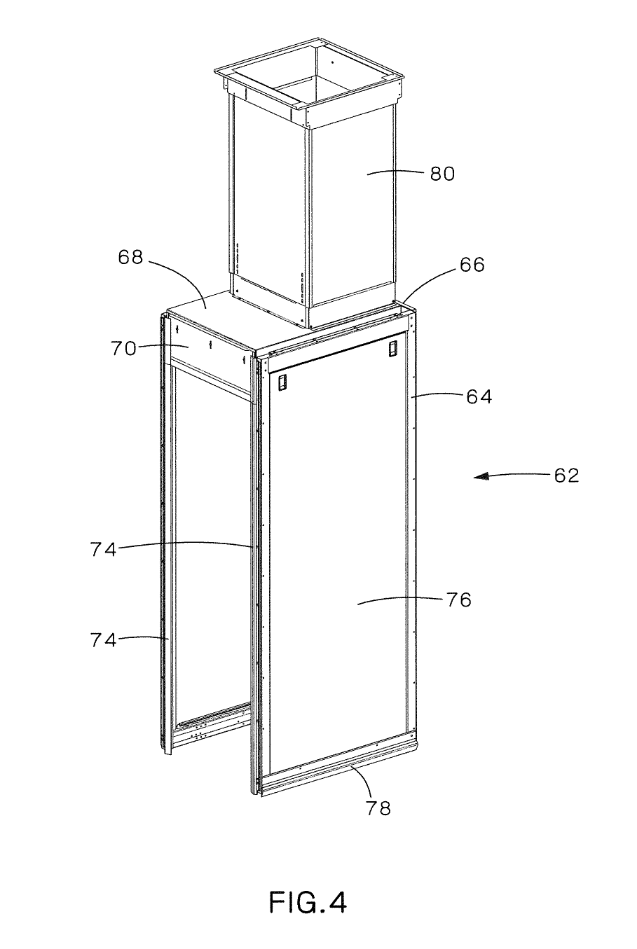

As illustrated in FIG. 4, a vertical exhaust duct 80 is positioned on the top of the docking frame 62 on top of the top support 68. The vertical exhaust duct 80 extends between the side frames 64, cross bar 66 and top support 68 to exhaust the hot air from the top of the docking frame 62.

The bay 60 also includes an adjustable upper seal plate 70 and a plurality of cabinet seals 74. Floor seals 78 are installed after the cabinet 150 is slid into the bay 60 (see FIG. 1). A side panel 76 and a floor seal 78 are attached to one of the side frames 64 if the bay 60 is intended to be positioned at the end of a row in the docking station 50.

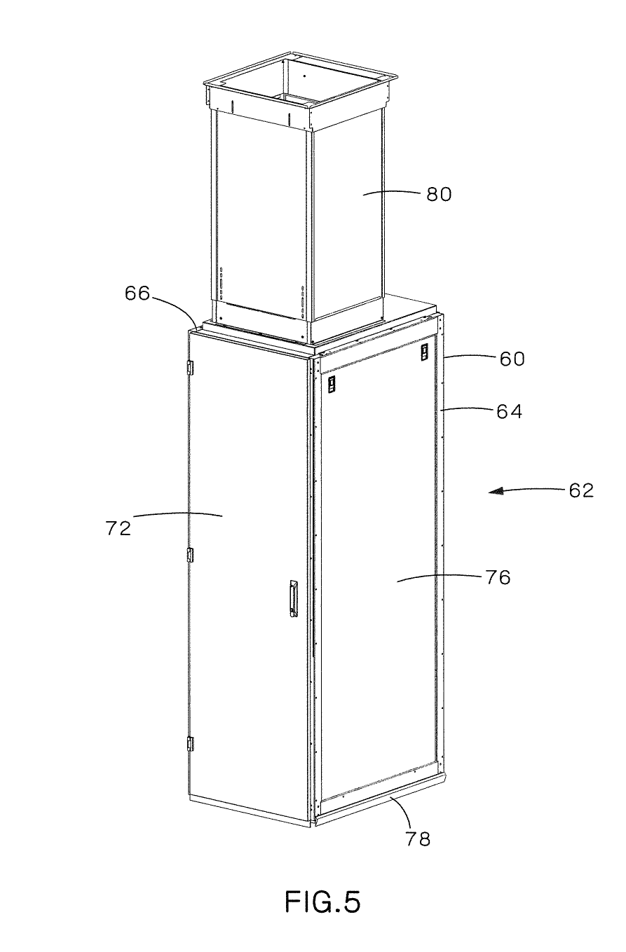

FIG. 5 illustrates the back of the bay 60 with a rear door 72 secured to the back of the side frames 64 to provide access to the back of the cabinet 150 installed therein.

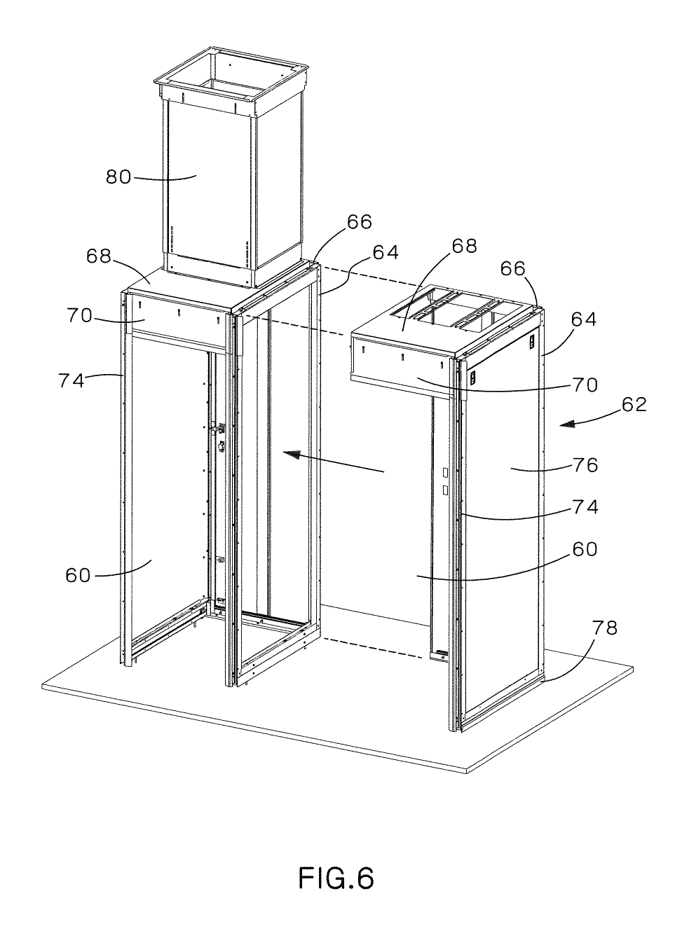

FIG. 6 illustrates the complete bay 60 of FIG. 5 positioned to receive an adjoining bay 60. The additional bay 60 includes only one side frame 64. The vertical exhaust duct 80 of the adjoining bay 60 has been removed for clarity. The side panel 76 and floor seals 78 are designed to be easily removed from the docking frame 62 when additional bays 60 are added to the docking station 50. Each bay 60 interlocks with adjoining bays 60 to form the modular docking station 50. As such, after the new bays 60 have been installed, the side panel 76 and floor seals 78 are reinstalled at the end of the row to seal the docking station 50.

Alternatively, the side panel 76 may be left on its original bay 60 or side panels may be added later between bays 60, if desired. As a result, the docking station 50 may be continuously expanded for additional cabinets 150 while maintaining the hot air containment in the docking station 50.

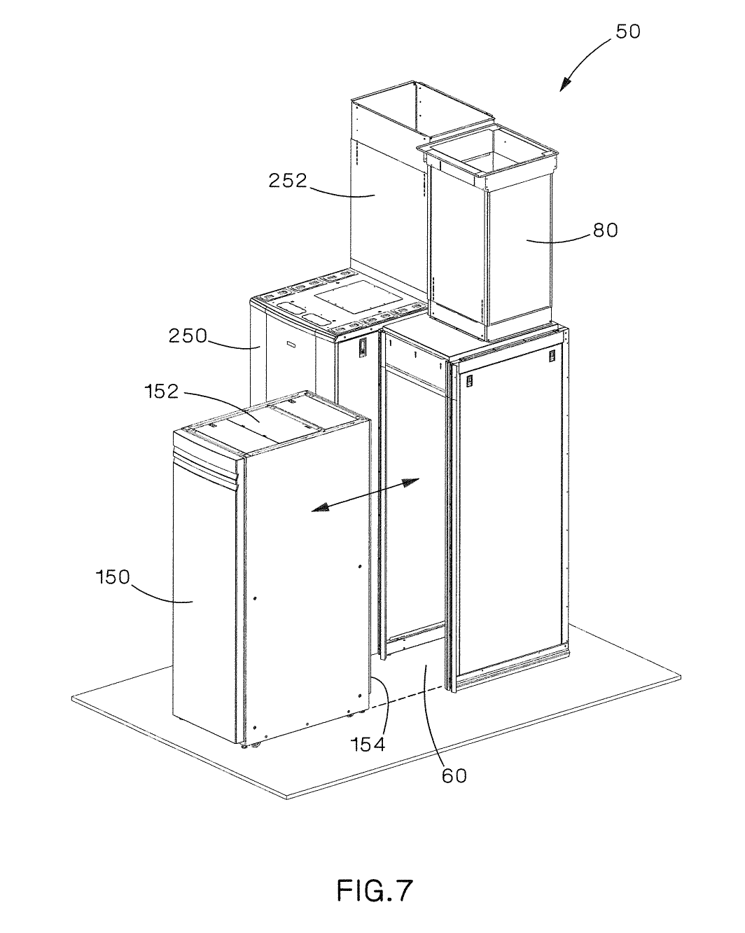

FIG. 7 illustrates an individual bay 60 of the modular docking station 50 positioned adjacent a Net-Access™ cabinet 250. A cabinet 150 is positioned to be slid into the individual bay 60. Each bay 60 is independent of the mating cabinet 150. As a result, the cabinet 150 is easily installed or removed from the bay 60. The cabinet 150 installed in the bay 60 of the docking station 50 includes a roof section 152 that is open or perforated and a rear door 154 that is perforated or removed to enable the hot air to be exhausted out of the cabinet 150 into the bay 60 and then out of the docking station 50 through the vertical exhaust duct 80.

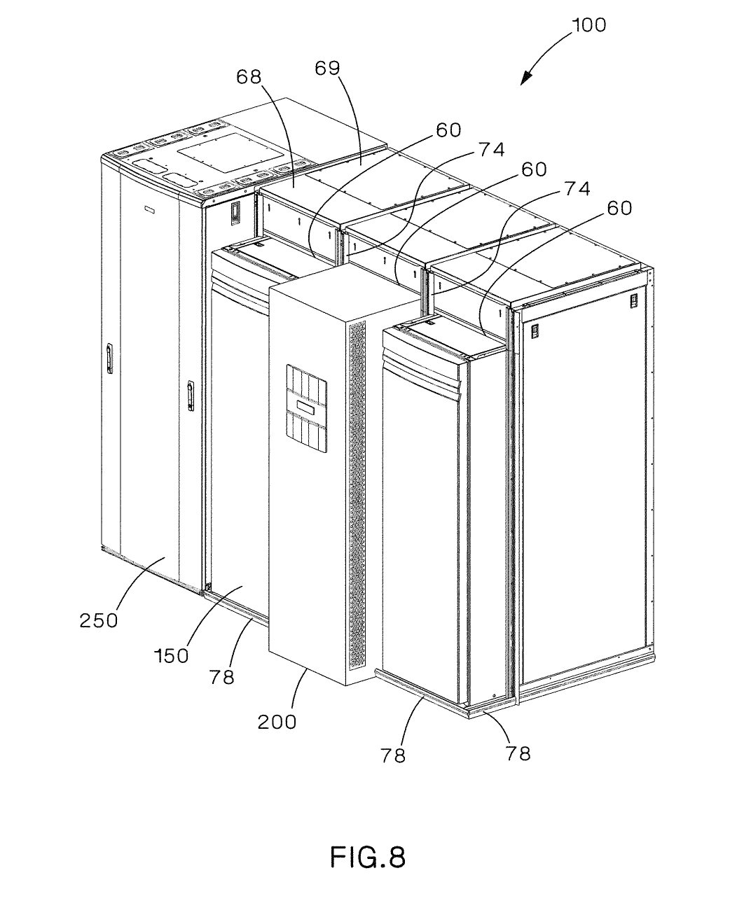

FIGS. 8-11 illustrate an alternative modular docking station 100 of the present invention with a cooling unit cabinet 200. FIG. 8 illustrates the front of the modular docking station 100 with a plurality of individual bays 60, cabinet seals 74 and floor seals 78. The bays 60 have a top support 68 and a second top support 69 that seal the top of the bay 60. The bays 60 hold cabinets 150 and a cooling unit cabinet 200.

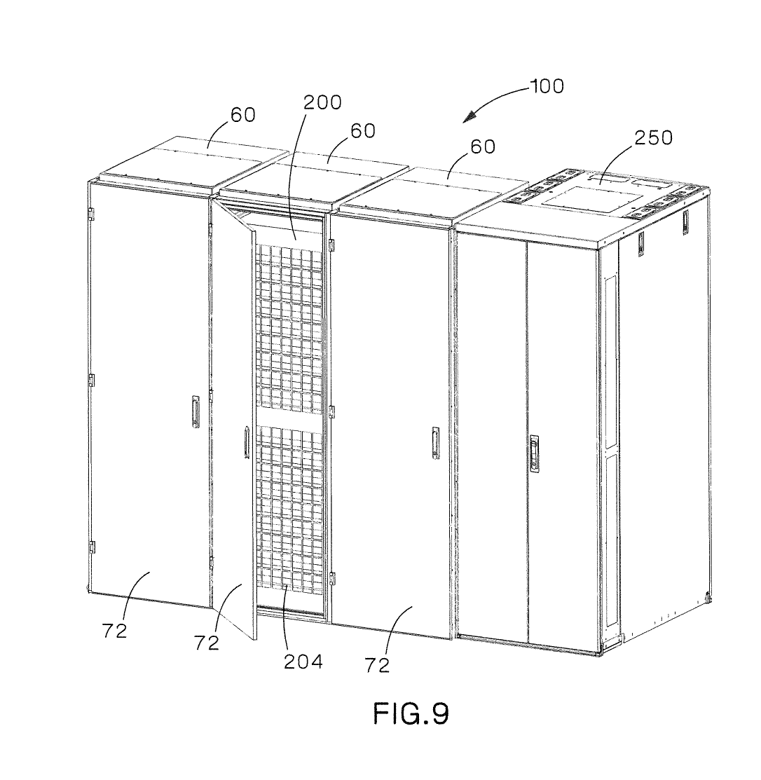

FIG. 9 illustrates the back of the modular docking station 100. As discussed above, cabling is accessible through the rear doors 72 of the bays 60 in the docking station that house the cabinets 150. FIG. 9 also illustrates the rear door 72 of the bay 60 that houses the cooling unit cabinet 200 which provides access to the cooling unit filters 204.

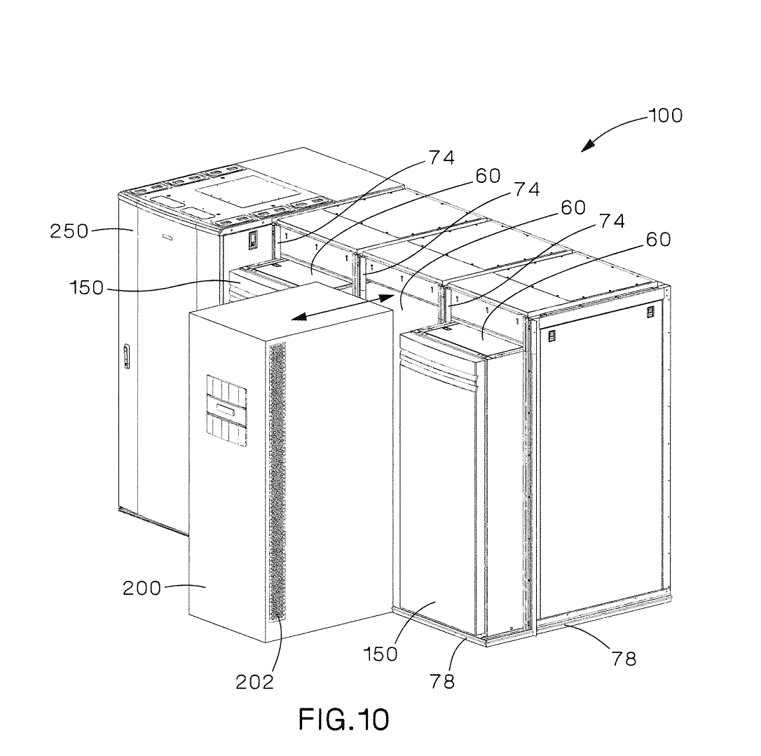

FIG. 10 illustrates the modular docking station 100 with the cooling unit cabinet 200 positioned to be installed in one of the bays 60. The cooling unit cabinet 200 includes a cool air venting area 202 located on each side of the cooling unit cabinet 200. The venting area 202 extends along each side of the cooling unit cabinet 200 to uniformly provide cool air to adjacent cabinets 150. Alternatively, the venting area may also be located on the front of the cooling unit cabinet 200. As discussed above, the modular docking station bays 60 are independent of the adjoining cabinets 150. As a result, cooling unit cabinets 200 may be installed in various locations, as desired.

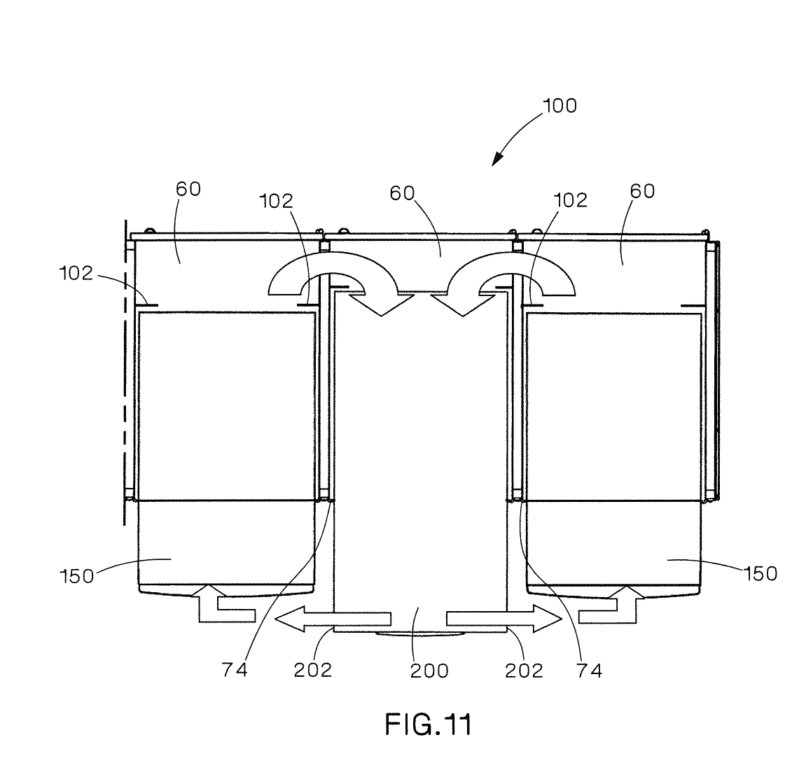

FIG. 11 illustrates the air flow in a partial modular docking station 100 with a cooling unit cabinet 200. Each cabinet 150 is installed in a bay 60 in the modular docking station 100 and a cooling unit cabinet 200 is installed in a bay 60 positioned between cabinets 150. Each bay 60 in the modular docking station 100 includes brackets 102 to provide a stop for the cabinets 150 and the cooling unit cabinet 200 to ensure proper placement in the bay 60. As such, the cooling unit cabinet 200 is aligned with the cabinets 150 within the modular docking station 100 to keep a consistent air flow pattern in the modular docking station 100.

As illustrated in FIG. 11, hot air exits the cabinets 150 and the bays 60 contain the hot air exhaust at the back of the cabinets 150. The cooling unit cabinet 200 draws in the hot air and converts the hot air into cooler air. The cooling unit cabinet 200 vents the cooler air out the side vents 202 of the cooling unit cabinet 200 along the front of the cabinets 150. This creates a circular system of continuous conversion of hot to cold air. The Net-Access™ cabinet 250 also includes an access port on the sides toward the rear of the cabinet 250. The access port may be removed to allow the hot air exhaust from the cabinet 250 to be pulled into the modular docking station 100.

As such, the modular docking station of the present invention provides a hot air containment system that vents hot air out of the docking station by vertical exhaust ducts or that recirculates hot air in the docking station through a cooling unit cabinet. The modular docking station accommodates various width storage cabinets and cooling unit cabinets. The docking station is modular to enable the user to create multiple configurations, as desired.

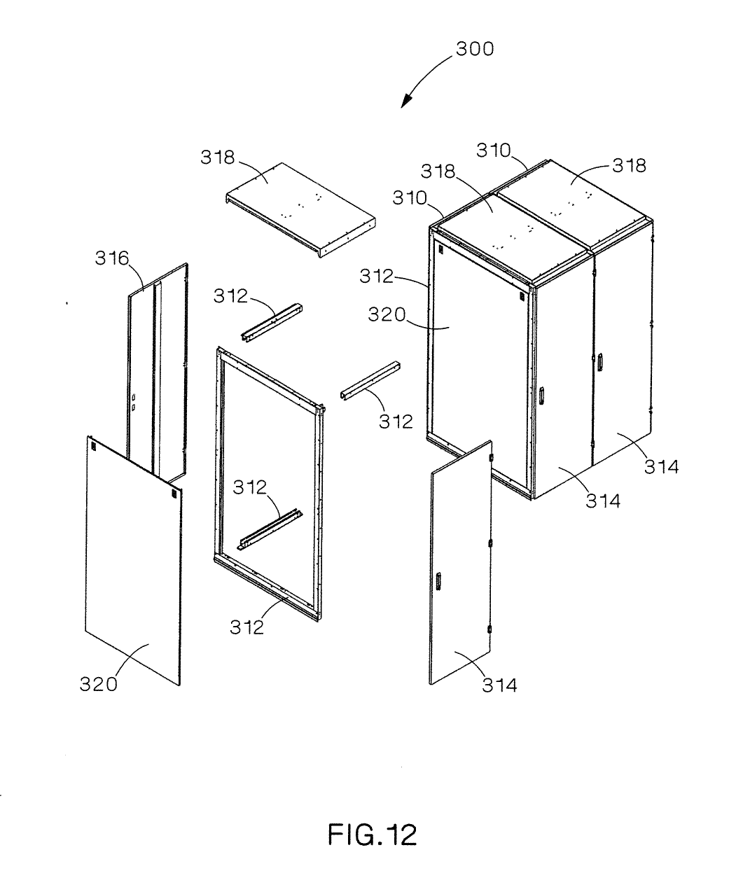

FIGS. 12-17 illustrate a modular containment system 300 designed to receive an equipment rack 350. As illustrated in FIG. 12, the modular containment system 300 is formed from a number of enclosures 310 that are secured to each other. Each enclosure 310 includes a modular frame 312, front and rear doors 314, 316 and a top panel 318. The front door 314, rear door 316 and top panel 318 may be solid or perforated. The enclosure 310 may also include a side panel 320. The enclosure 310 can be shipped unassembled for efficiency.

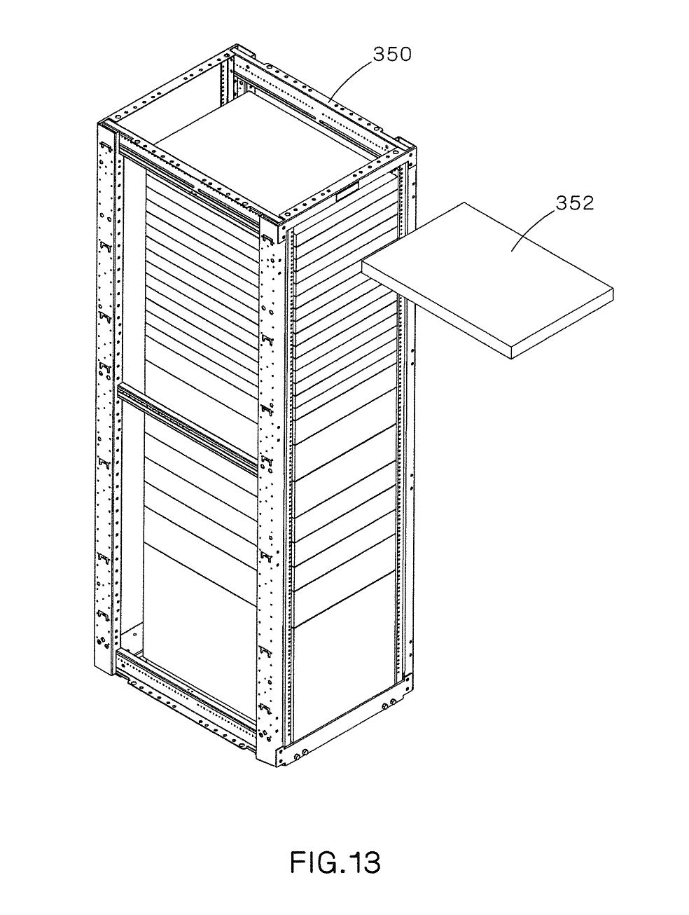

FIG. 13 illustrates the equipment rack 350 with equipment 352 positioned to be installed in the rack 350. The modular containment system 300 is designed to accommodate equipment racks 350 having a variety of dimensions to accommodate many configurations. The equipment rack 350 includes casters and cable management features (not illustrated) to manage cabling between the equipment 352 installed in the equipment rack 350. The equipment rack 350 is also strong enough to support pre-assembled equipment during shipping.

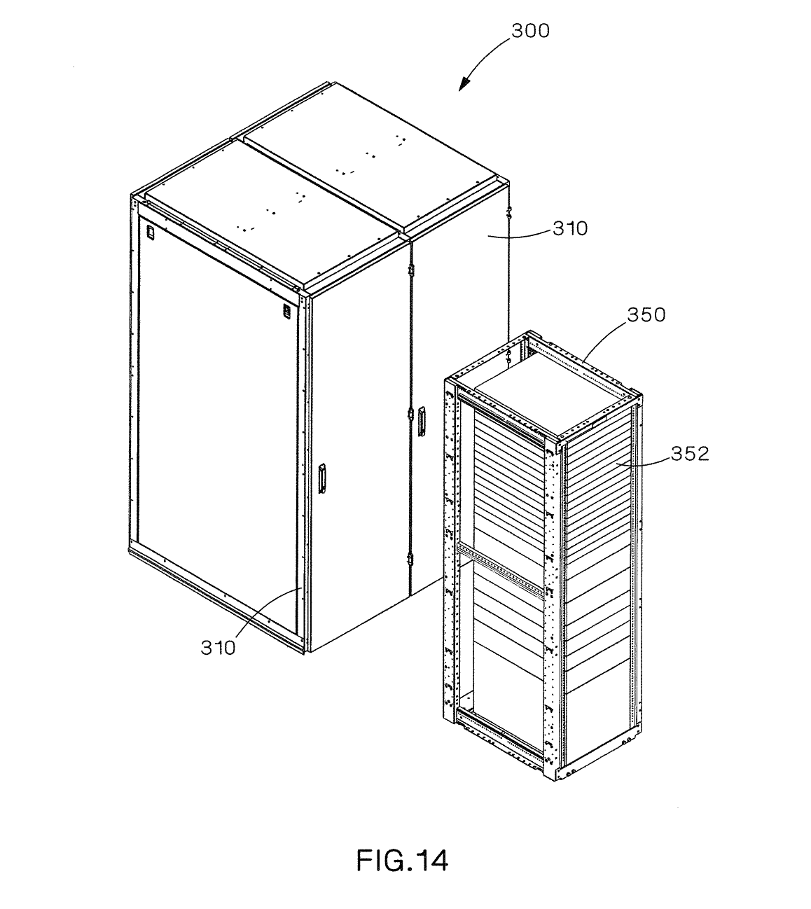

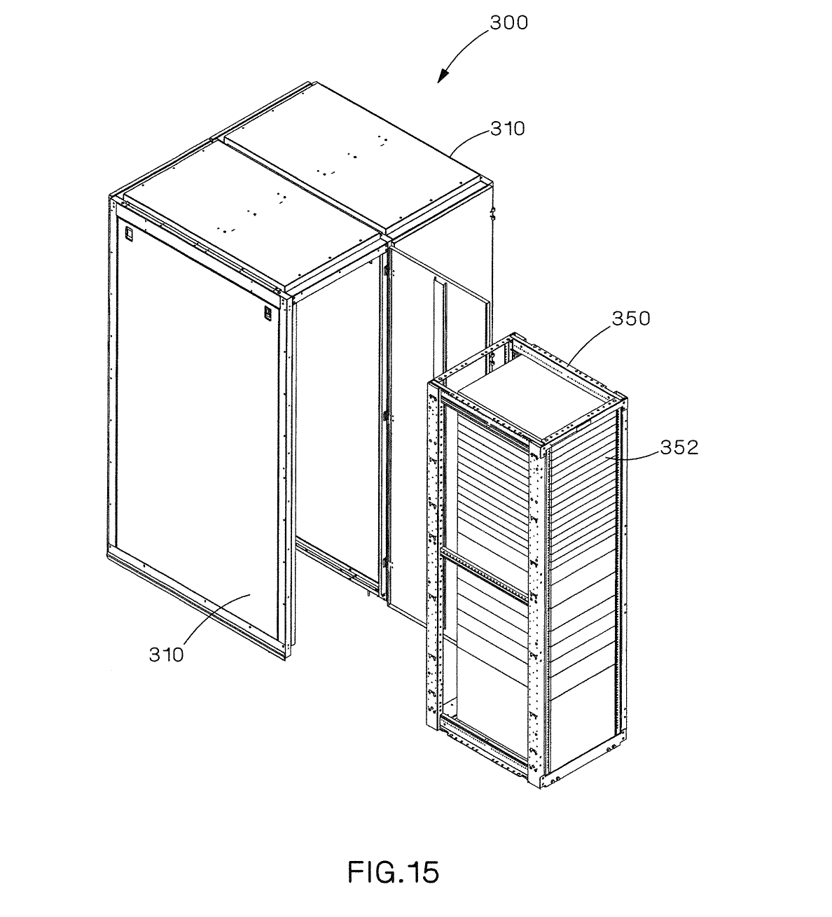

FIGS. 14 and 15 illustrate the equipment rack 350 and the modular containment system 300. Once the enclosure 310 has been constructed and the equipment rack 350 is populated with equipment 352, the equipment rack 350 is ready to be rolled into the enclosure 310. The enclosure 310 is designed with a depth that is larger than the equipment racks 350. As a result, the equipment rack 350 may be positioned at various depths when installed in the enclosure. Varying the depth of the equipment rack 350 will enable more air to travel in front or behind the equipment rack 350, as desired, thereby balancing the hot or cold plenums in the enclosure 310.

After the equipment racks 350 have been positioned in the enclosure 310, cabling can be connected to the equipment 352. The benefit of having a mobile equipment rack 350 is that the equipment rack 350 can be removed, modified or replaced quickly while the cooling system, intra-cabinet cabling and power remains undisturbed. Thus, network cabling and power cables could stay attached to the equipment rack 350 depending on the user's requirements.

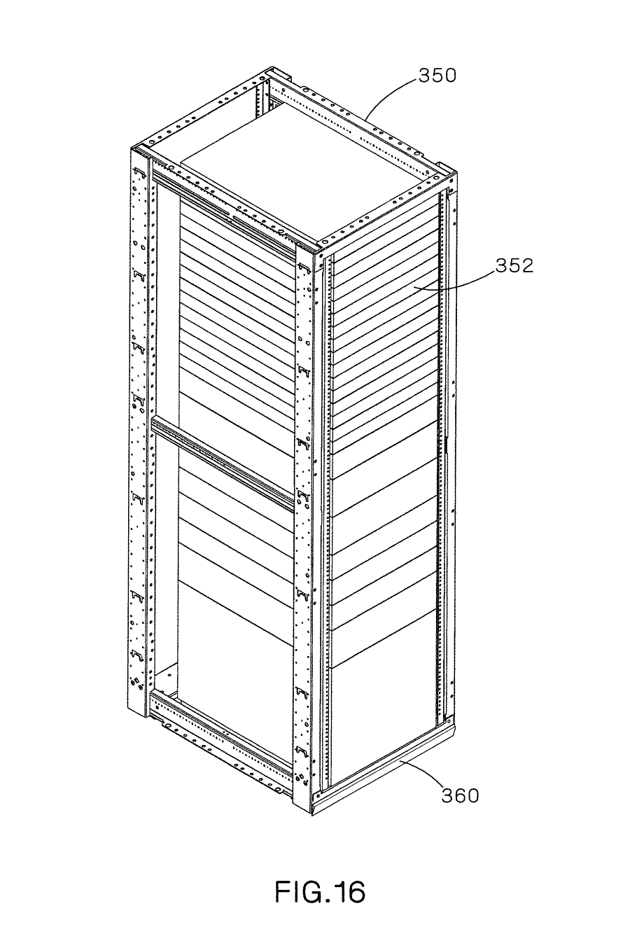

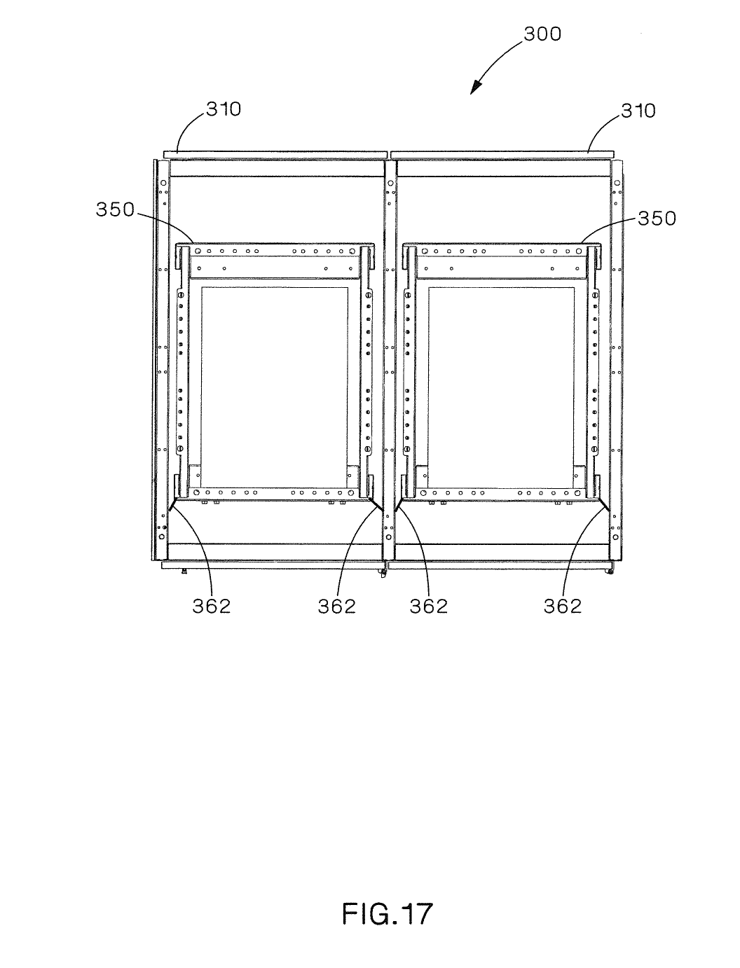

FIG. 16 illustrates the equipment rack 350 with a bottom seal 360 attached thereto. The bottom seal 360 is necessary to prevent the mixing of hot and cold air. FIG. 17 illustrates a top view of equipment racks 350 installed in adjacent enclosures 310 in the modular containment system 300. Vertical flap seals 362 and a top seal (not illustrated) are attached to the enclosure 310 to prevent the mixing of hot and cold air. The vertical flap seals 362 may be positioned along the depth of the enclosure 310. The vertical flap seals 362 could slide back to front, as desired, depending on where the equipment rack 350 is positioned within the enclosure 310.

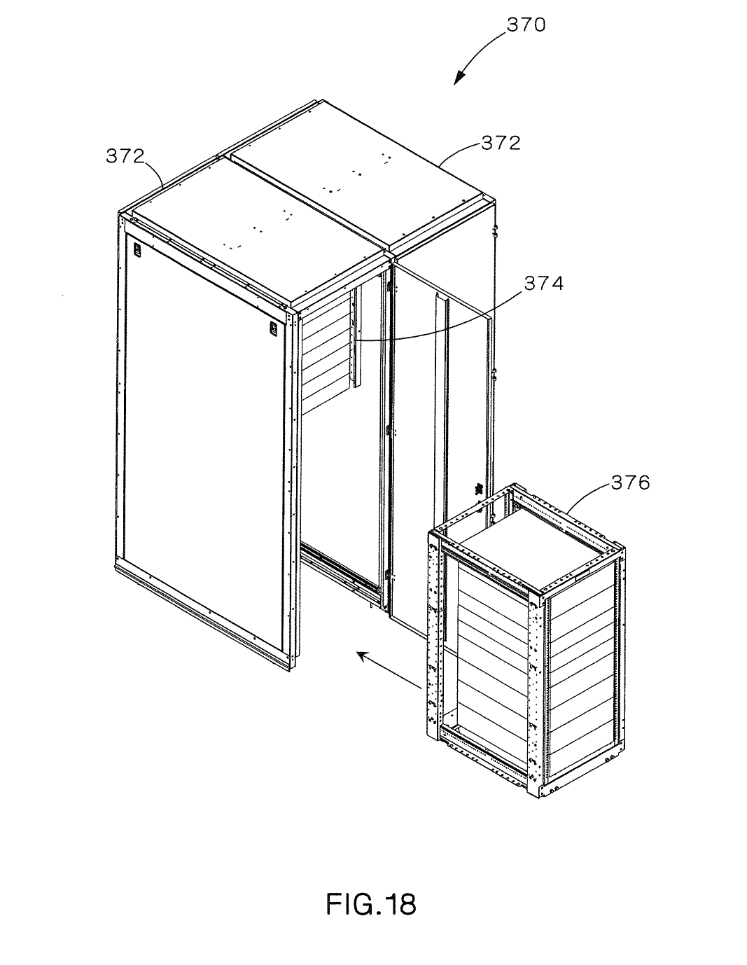

FIG. 18 illustrates an alternative modular containment system 370. The enclosure 372 in the alternative modular containment system is designed to receive an equipment rack 376 having various heights. As a result, the enclosure 372 may include stationary equipment mounting rails 374. The stationary equipment mounting rails 374 would enable a patch field, network switches or other equipment to remain in the enclosure while the equipment rack 376 is removed.

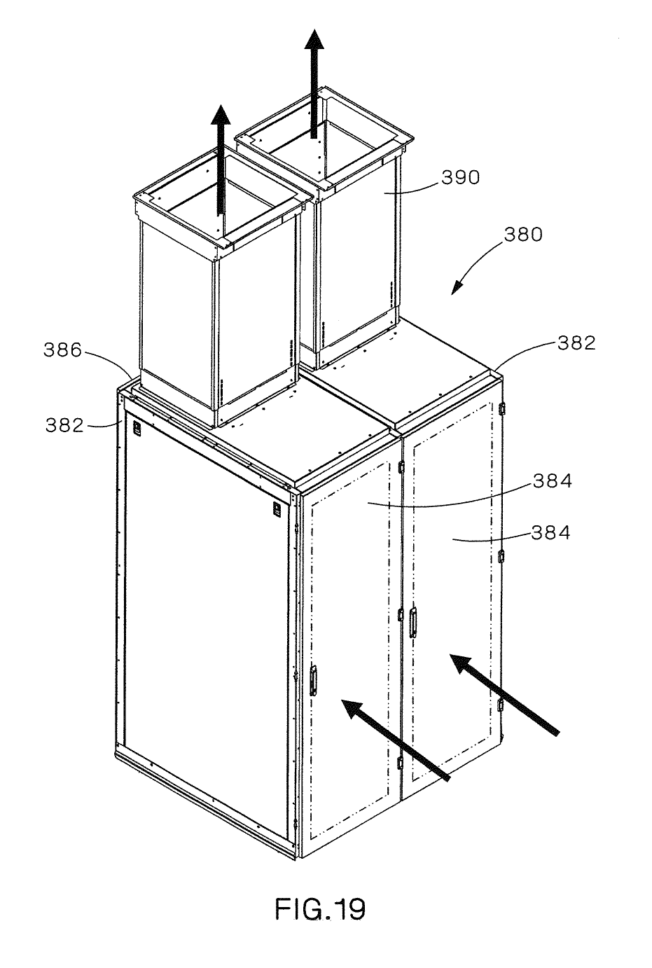

FIG. 19 illustrates an alternative modular containment system 380 with vertical exhaust ducts 390 secured to the enclosures 382. The front door 384 of the enclosure 382 is perforated to allow cold air to enter the system to cool the equipment positioned therein. The rear door 386 of the enclosure 382 would be solid to force the hot air up through the vertical exhaust duct 390.

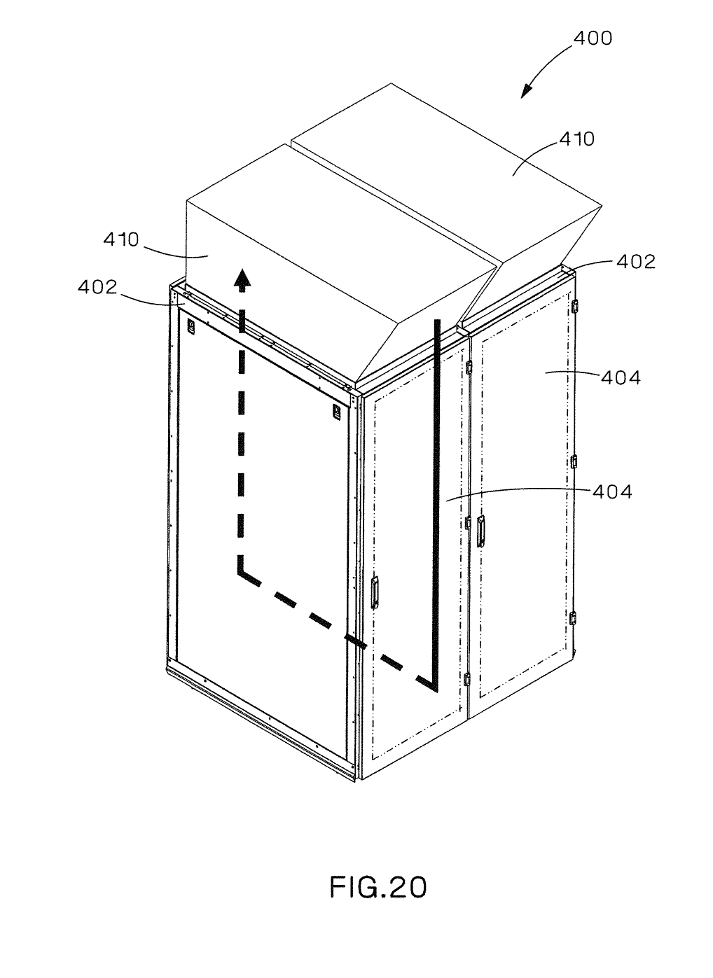

FIG. 20 illustrates an alternative modular containment system 400 with an air conditioning unit 410 mounted to the top of the enclosures 402. The air conditioning unit 410 would blow cold air down through the perforated front doors 404 of the enclosure 402 to cool the equipment. The hot air is directed back up to the inlet of the air conditioning unit 410 to be cooled.

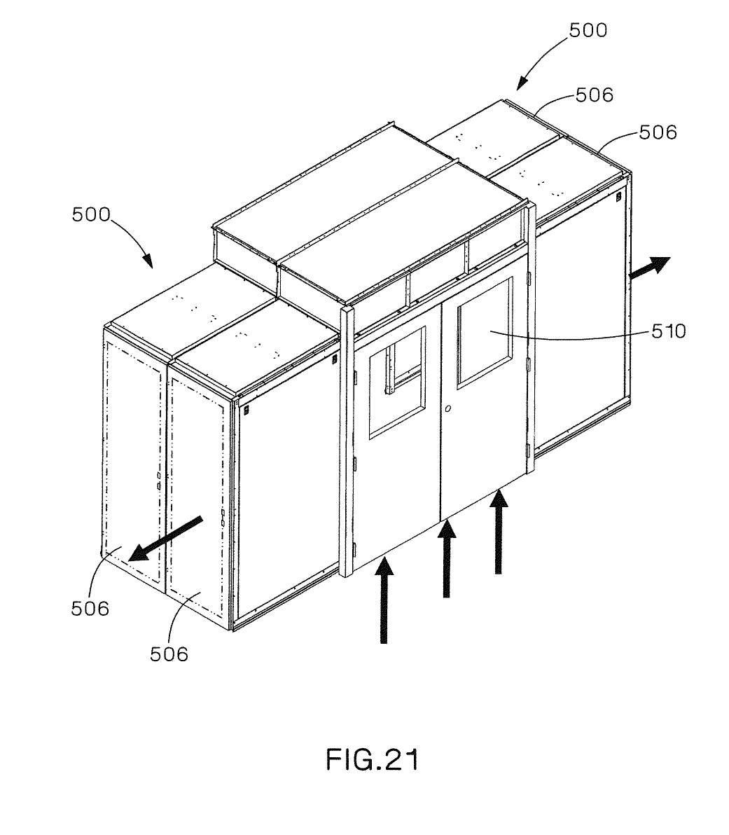

As shown in FIG. 21, the modular containment system 500 is designed to be compatible with a cold aisle containment configuration. The modular containment system 500 is positioned on each side of an aisle 510. A structure is built over the aisle 510 to contain the air therein. Cool air enters the aisle 510 through the floor to cool the equipment in the modular containment system 500. The hot air would exit the modular containment system 500 through perforated rear doors 506. The modular containment system 500 may also be used in a hot aisle configuration.

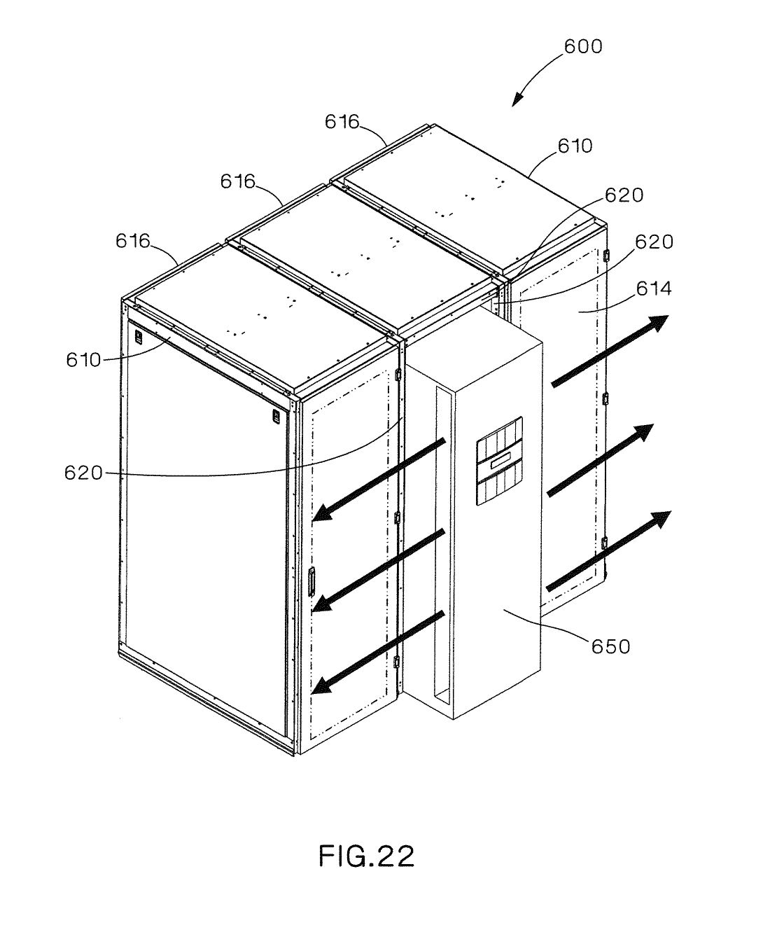

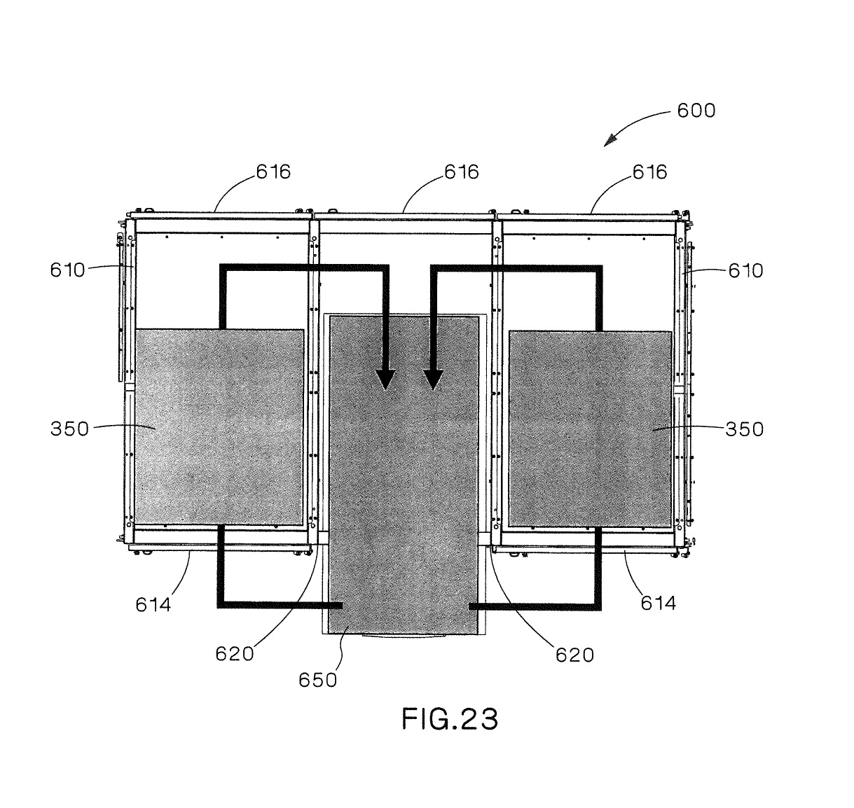

FIGS. 22-25 illustrate an alternative modular containment system 600 with an in-row cooler 650 installed in an enclosure 610. As illustrated in FIGS. 22-23, the in-row cooler protrudes from the enclosure 610 in order to blow cold air in front of the modular containment system 600 similar to the cooling unit 200 discussed above with respect to FIGS. 8-11. The modular containment system 600 also includes a plurality of perimeter flap seals 620 located between the in-row cooler 650 and the enclosure 610. The in-row cooler 650 draws hot equipment exhaust air from the back of the enclosure 610. The in-row cooler 650 cools the hot air and then blows the cool air out in front of the adjacent enclosures 610 as illustrated in FIG. 23.

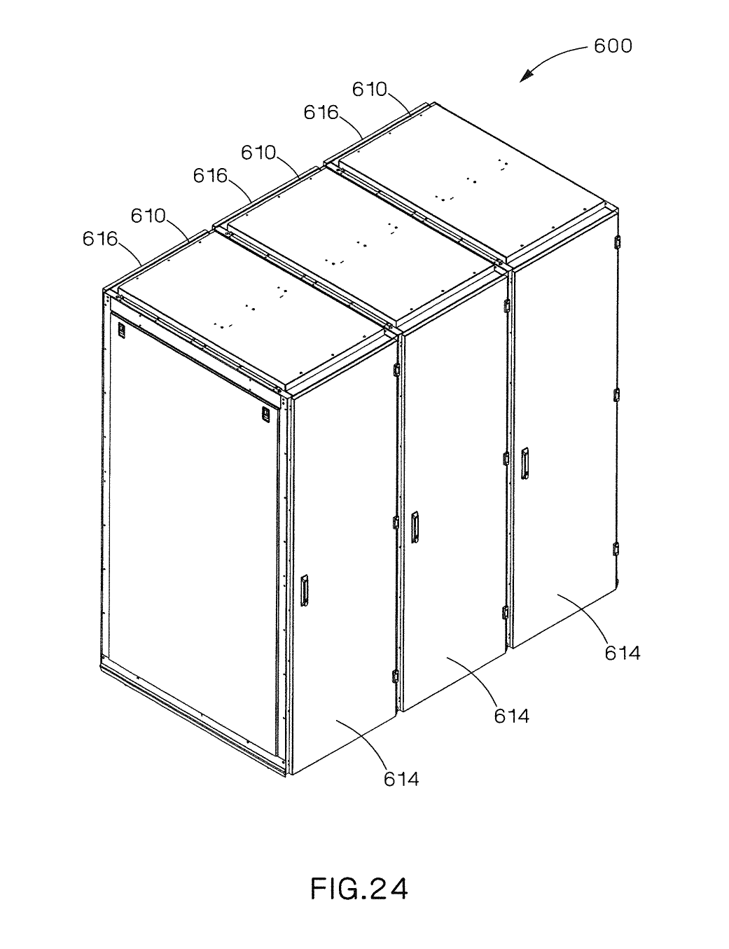

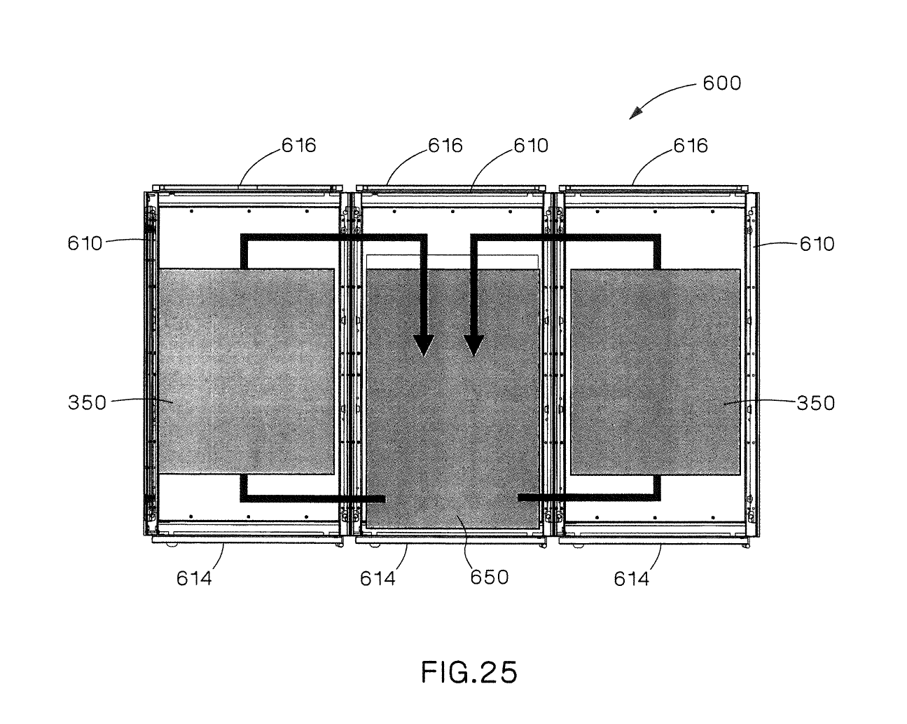

FIGS. 24-25 illustrate the in-row cooler 650 installed completely within the enclosure 610. Each enclosure 610 would include solid front and rear doors, 614, 616, respectively, to enable the air flow to be contained within the modular containment system 600. As such, air from the in-row cooler 650 would flow through a chamber in front of the equipment rack 350, through the equipment 352 and back to the in-row cooler 650 in the rear portion of the modular containment system 600. Thus, the in-row cooler, regardless of its location in the modular containment system, and the modular containment system create a circular system of continuous conversion of hot to cold air.

Furthermore, while the particular preferred embodiments of the present invention have been shown and described, it will be obvious to those skilled in the art that changes and modifications may be made without departing from the teaching of the invention. The matter set forth in the foregoing description and accompanying drawings is offered by way of illustration only and not as limitation.

1. A modular containment system for redirecting exhaust from cabinets without altering the cabinet, the modular containment system comprising:
a docking station having a first bay, wherein the first bay having a first side frame and a second side frame, a top support joins the first and second side frames, and cross bars join the first and second side frames;
a second bay connected to the first bay, wherein the second bay having a third side frame, cross bars that join the second and third side frames, and a top support that joins the second and third side frames; and
at least one cabinet positioned within one of the first and second bays of the docking station.

2. The modular containment system of claim 1, wherein the side frames having a front and a back, the cross bars connecting the back of the side frames and the top support extending between the front of the side frames.

3. The modular containment system of claim 1, wherein each bay having cabinet seals positioned along the side frames for providing a seal with the cabinet positioned therein.

4. The modular containment system of claim 1, wherein each bay having an adjustable upper seal positioned at a front of the bay for providing a seal with the cabinet positioned therein.

5. The modular containment system of claim 1, wherein one of the bays further comprising a side panel and a floor seal for sealing the end of a row in the docking station.

6. The modular containment system of claim 1, wherein each bay includes a solid rear door for providing access to the cabinet installed therein.

7. The modular containment system of claim 1, further comprising an adjoining bay having a side frame, cross bars that join adjacent side frames, and a top support that joins the adjacent side frames.

8. The modular containment system of claim 7, wherein a side panel and floor seals are installed on a last adjoining bay to seal an end of the row in the docking station.

9. The modular containment system of claim 1, wherein the top supports of the bays completely seal the top of the bays.

10. The modular containment system of claim 1, wherein a vertical exhaust duct is positioned on each bay for directing contained air out of the system.

11. The modular containment system of claim 1, further comprising a cooling unit positioned within one of the bays for drawing hot air exhausted from the cabinets, converting hot air to cool air, and expelling cool air in front of the cabinets.

12. The modular containment system of claim 11, wherein the cooling unit is positioned with a front portion of the cooling unit extending out of the bay, whereby cool air exits the cooling unit through a cool air venting area to cool the cabinets positioned in adjacent bays.

13. The modular containment system of claim 11, wherein each bay includes brackets for providing a stop for the cabinets and cooling unit to ensure proper positioning in the bay.

14. The modular containment system of claim 11, wherein the cooling unit is completely enclosed in the bay, whereby cool air flows out of cooling unit in the bay, through the cabinets, and exhausted hot air flows back into the cooling unit.
